(19) United States
(12) Patent Application Publication
(10) Pub. No.: US 2018/0331324 A1
(43) Pub. Date: Nov. 15, 2018

(54) LIGHT OUT-COUPLING IN ORGANIC LIGHT-EMITTING DIODES (OLED)

(71) Applicant: a.u. Vista Inc., Milpitas, CA (US)

(72) Inventors: Seok-Lyul Lee, Hsinchu (TW); Fang-Chen Luo, Milpitas, CA (US); Adiel Abileah, Milpitas, CA (US)

(21) Appl. No.: 15/591,236

(22) Filed: May 10, 2017

(51) Int. Cl. H01L 51/52; H01L 51/00; H01L 51/50; H01L 51/56

(52) U.S. Cl. CPC H01L 51/5268; H01L 51/0096; H01L 51/5092; H01L 51/56; H01L 51/5072; H01L 51/5221; H01L 51/5206; H01L 51/5056

(57) ABSTRACT

An improved organic light-emitting diode (OLED) structure is shown with irregularities that are formed on a substrate by depositing processes and etching processes. OLED stack layers are deposited atop the irregularities, thereby increasing scattering and improving light out-coupling from the improved OLED structure.

### BACKGROUND

### Field of the Disclosure

The present disclosure relates generally to organic light-emitting diodes (OLED) and, more particularly, to improved light out-coupling in OLED.

### Description of Related Art

Organic light-emitting diodes (OLED) have a variety of uses, including for television screens, computer monitors, or other display-related applications. In order for OLED-based displays to work properly, light that is generated by the OLED must be emitted from the OLED. The brightness of the emitted light is related to out-coupling efficiency of the OLED. As such, there are ongoing efforts to improve light out-coupling in OLED.

### SUMMARY

An improved organic light-emitting diode (OLED) layer structure is shown with irregularities that are formed on a substrate by depositing processes and etching processes. OLED stack layers are deposited atop the irregularities, thereby increasing scattering and improving light out-coupling from the improved OLED structure.

Other systems, devices, methods, features, and advantages will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A is a diagram illustrating bottom emission of light through layers of a conventional organic light-emitting diode (OLED) structure.

FIG. 1B is a diagram illustrating both trapped light in the OLED and out-coupling of light from the OLED of FIG. 1A.

FIG. 2 is a diagram illustrating bottom emission of light through layers in one embodiment of an OLED with improved light out-coupling.

FIG. 3 is a diagram illustrating, in greater detail, the substrate and the irregularities that are shown in FIG. 2.

FIG. 4A is a flowchart showing one embodiment of a process for manufacturing an OLED with improved light out-coupling.

FIG. 4B is a diagram showing embodiments of resulting structures for each process step of FIG. 4A.

### DETAILED DESCRIPTION OF THE EMBODIMENTS

In recent years, technology for organic light-emitting diodes (OLED) has advanced considerably. The efficiency and lifetime for OLED devices have improved dramatically and numerous OLED displays have enjoyed commercial success. This is because OLED have many attractive features, including brightness, energy efficiency, wider viewing angles (when used in displays), quicker response times than conventional systems, and lowered manufacturing costs due to their ability to be fabricated by depositing or printing organic materials onto a single substrate.

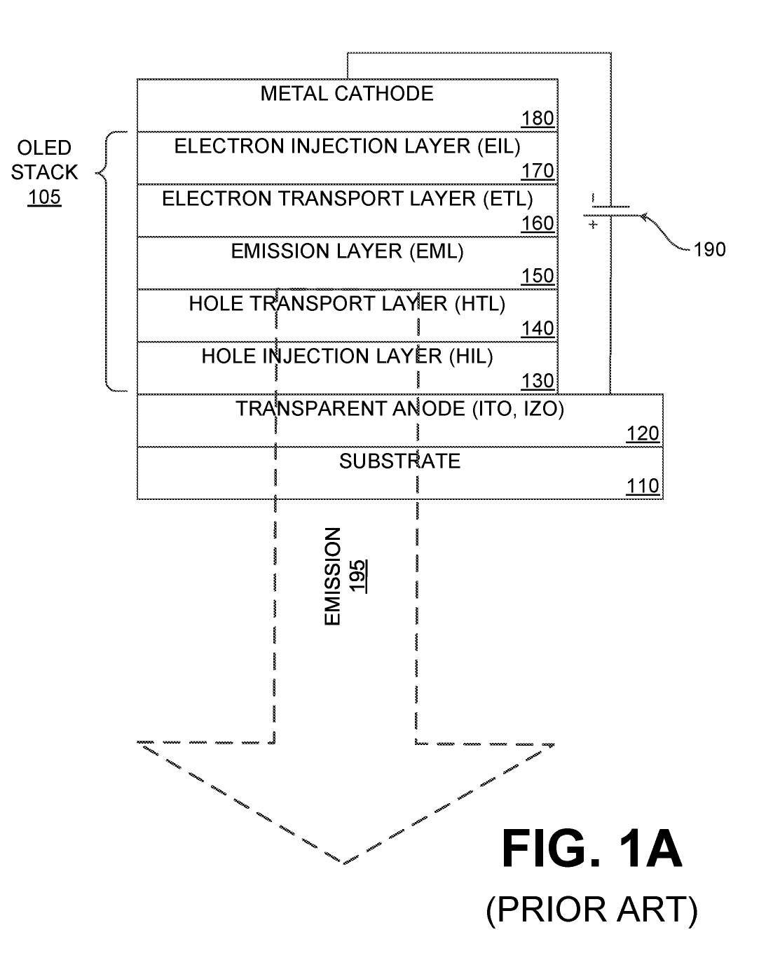

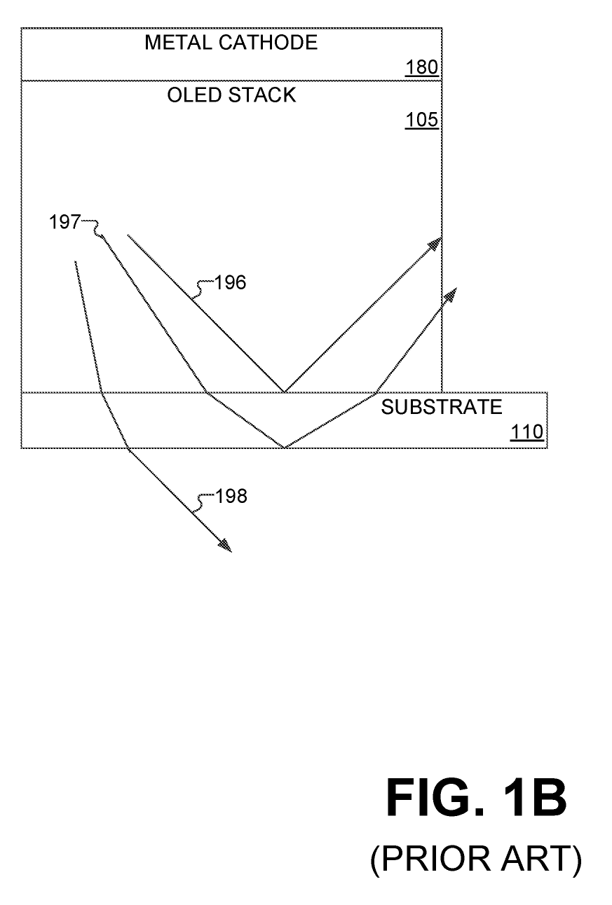

As shown in FIG. 1A, a conventional OLED comprises an OLED stack 105 with a hole injection layer (HIL) 130, a hole transport layer (HTL) 140 deposited adjacently onto the HIL 130, an emission layer (EML) 150 deposited adjacently onto the HTL 140, an electron transport layer (ETL) 160 deposited adjacently onto the EML 150, and an electron injection layer (EIL) 170 deposited adjacently onto the ETL 160. This entire OLED stack 105 resides between a transparent anode 120 and a metal cathode 180, with the transparent anode 120 being deposited onto a substrate 110. Electrical current is injected into the OLED stack 105 by applying an electrical bias 190 (or driving voltage) across the transparent anode 120 and the metal cathode 180, which results in emission 195. The brightness of the emission 195 is determined by how much light is trapped within the OLED stack 105 and how much light can be out-coupled from the OLED stack 105.

As shown in FIG. 1B, due to differences in indices of refraction for the various layers, some of the light 196 is trapped within the OLED stack 105 and some of the light 197 by the substrate 110. Thus, out-coupled light 198 accounts for only a fraction (approximately twenty percent (20%) to 25%) of the total light generated in the OLED stack 105.

Others have attempted to improve light out-coupling by providing buckles stamped underneath the OLED structure by thermal evaporation of aluminum (Al) films on polydimethylsiloxane (PDMS) substrates. Although PDMS stamps on ultraviolet (UV) curable resins prior to sputtering the transparent anode may be suitable for small-scale OLED structures, the process becomes commercially unfeasible for larger substrates, such as those for large-screen televisions. This is because ultraviolet (UV) curable resins such as acryl have weak thermal stability and results in out-gassing problems and shape distortions at high temperatures.

In view of these problems, this disclosure teaches an OLED with improved light out-coupling by providing irregularities that increase light scattering and, thus, improve light out-coupling. Specifically, the irregularities are formed on a substrate by depositing etchable layers onto the substrate and etching irregularities into the deposited layers. For clarity, etchable layers are layers that can be etched using various etchants. For example, if an etchable layer is silica-based, then the etchant can be hydrofluoric acid (HF), a buffered HF (BHF), a buffered oxide etchant (BOE), or other chemicals that can etch silica.

The etchable layers comprise an upper, lower-density, higher-etching rate layer and a lower, higher-density, lower-etching-rate layer. Consequently, when etched, the resulting structures are smoothly-tapered microbumps. For clarity, microbumps are micrometer (μm) scale bumps. These microbumps provide increased scattering of light, thereby improving the light out-coupling from the OLED.

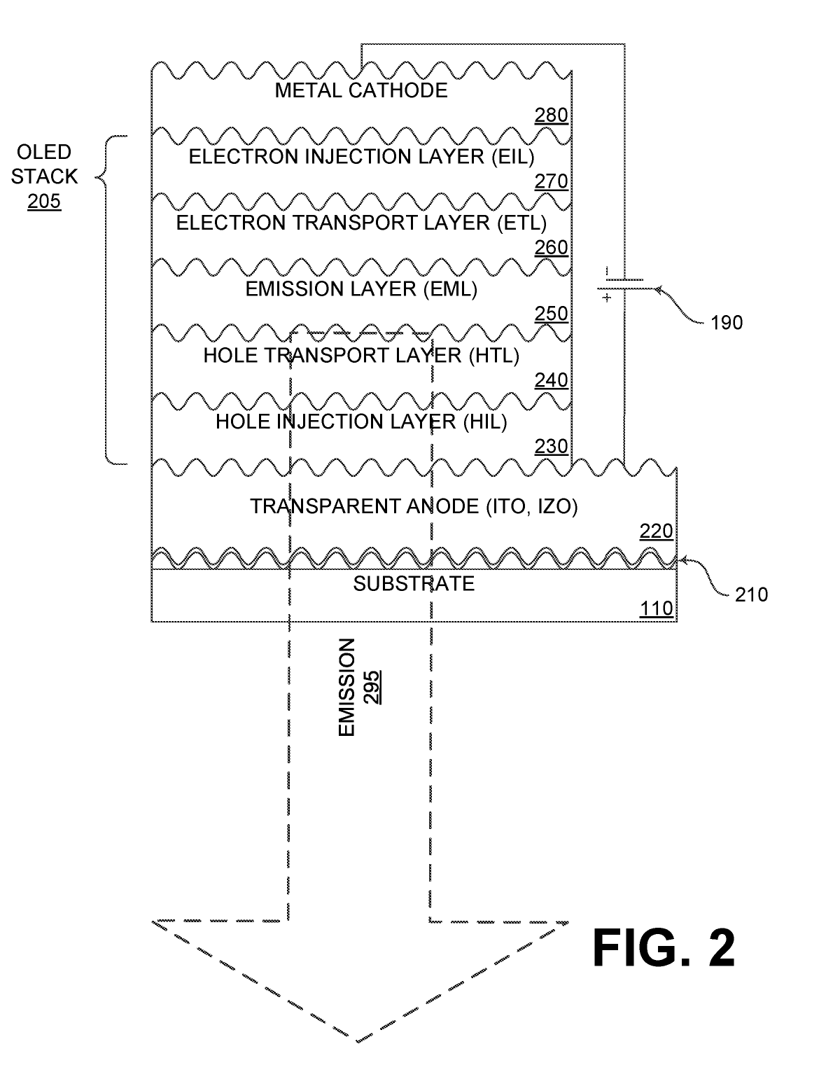

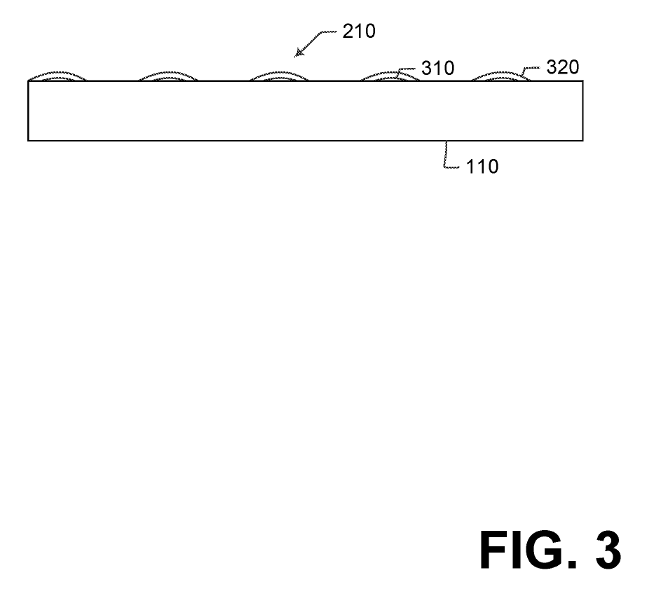

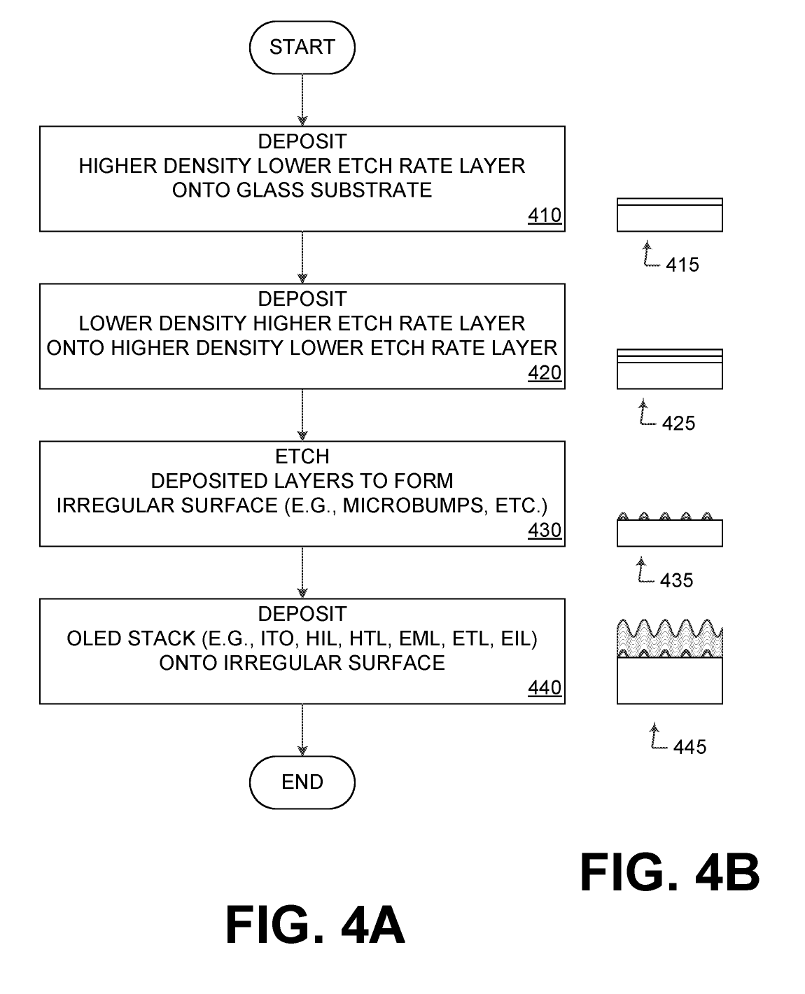

Having provided a broad description of an embodiment of an OLED with improved light out-coupling, reference is now made in detail to the description of the embodiments as illustrated in the drawings. Specifically, FIGS. 2 and 3 show embodiments of OLED structures having improved light out-coupling, while FIGS. 4A and 4B show embodiments of processes for manufacturing OLED with improved light out-coupling. While several embodiments are described in connection with these drawings, there is no intent to limit the disclosure to the embodiment or embodiments disclosed herein. On the contrary, the intent is to cover all alternatives, modifications, and equivalents.

FIG. 2 is a diagram illustrating bottom emission of light through layers in one embodiment of an OLED with improved light out-coupling. As shown in FIG. 2, the OLED structure comprises a substrate 110. Unlike conventional OLED structures, the embodiment of FIG. 2 comprises irregularities 210 that are formed above the substrate 110. FIG. 3 is a diagram illustrating, in greater detail, the substrate 110 and the irregularities 210 that are shown in FIG. 2. As shown in FIG. 3, these irregularities comprise a lower etchable layer 310 and an upper etchable layer 320. Preferably, the irregularities 210 are smoothly tapered such that there are no sharp angles where the irregularities 210 interface the substrate 110. For some embodiments, the substrate 110 is a transparent glass substrate with an index of refraction of approximately 1.5.

The lower etchable layer 310 is interposed between the upper etchable layer 320 and the substrate 110. The lower etchable layer 310 has an index of refraction that is higher than the index of refraction of the substrate 110. For example, the index of refraction for some embodiments of the lower etchable layer 310 is approximately 1.6. It should be appreciated that, for other embodiments in which the index of refraction of the substrate 110 is lower than 1.5, the index of refraction for the lower etchable layer 310 can be between approximately 1.4 and approximately 1.5. For some embodiments, the lower etchable layer 310 comprises a silicon oxide (SiOx), a silicon nitride (SiNx), a silicon oxynitride (SiOxNy), or combinations thereof.

The lower etchable layer 310 has a density that is higher than the density of the upper etchable layer 320. Furthermore, the lower etchable layer 310 has an etching rate that is lower than the etching rate of the upper etchable layer 320. Additionally, the upper etchable layer 320 has an index of refraction that is higher than the index of refraction of the lower etchable layer 310. For example, the index of refraction for some embodiments of the upper etchable layer 320 is approximately 1.7. For other embodiments, such as those where the index of refraction for the lower etchable layer 310 is between approximately 1.4 and approximately 1.5, the index of refraction for the upper etchable layer 320 can be between approximately 1.6 and approximately 1.7. For some embodiments, the upper etchable layer 320 comprises a silicon oxide (SiOx), a silicon nitride (SiNx), a silicon oxynitride (SiOxNy), or combinations thereof.

The upper etchable layer 320 and the lower etchable layer 310, when etched using, for example, approximately 1 to approximately 4 weight percent (wt %) hydrofluoric acid (HF), results in irregularities 210 that cause light scattering. Preferably, these irregularities are light-defracting microbumps.

Continuing with FIG. 2, a substantially-transparent anode layer 220 is formed above the substrate 110 and the irregularities 210. The anode layer 220 has a refractive index that is greater than the refractive indices of the irregularities 210. Thus, for example, if the upper etchable layer has a refractive index of approximately 1.7, then the refractive index of the anode layer 220 may be approximately 1.8. For some embodiments, the anode layer 220 comprises indium tin oxide (ITO), indium zinc oxide (IZO), or any combination thereof.

The OLED structure of FIG. 2 also comprises a metal cathode layer 280, which in combination with the anode layer 220 permits application of a driving voltage 190 between the anode layer 220 and the cathode layer 280. For some embodiments, the metal cathode layer 280 comprises aluminum (Al), silver (Ag), or any combination thereof. For some embodiments, the metal cathode layer 280 reflects most of light emitting from emission layer 250 of OLED stack 205 such that light from emission layer 250 can emit toward substrate 110. For some embodiment, the metal cathode layer 280 is opaque.

In the embodiment of FIG. 2, an OLED stack 205 is formed between the anode layer 220 and the cathode layer 280. As shown in FIG. 2, the OLED stack 205 comprises a hole injection layer (HIL) 230, a hole transport layer (HTL) 240 deposited adjacently onto the HIL 230, an emission layer (EML) 250 deposited adjacently onto the HTL 240, an electron transport layer (ETL) 260 deposited adjacently onto the EML 250, and an electron injection layer (EIL) 270 deposited adjacently onto the ETL 260.

As shown in FIG. 2, when the driving voltage 190 is applied across the OLED stack 205, the resulting light produced from the EML 250 is out-coupled as light emission 295. Unlike the light emissions 195, 196, 197, 198 from the structures of FIGS. 1A and 1B, the out-coupled light emission 295 of FIG. 2 is brighter because of the scattering caused by the irregularities 210. In other words, the embodiment of FIG. 2 provides improved light out-coupling as compared to the conventional OLED structure of FIG. 1A.

As those having skill in the art can appreciate, the microbumps with the etchable characteristics and indices of refraction, as described above, provide a refraction mechanism that results in improved light out-coupling from the OLED structure.

In addition to providing an improved OLED structure for light out-coupling, this disclosure also provides a method for fabricating such an improved OLED structure, which are explained with reference to FIGS. 4A and 4B. Specifically, FIG. 4A is a flowchart showing one embodiment of a process for manufacturing an OLED with improved light out-coupling, while FIG. 4B is a diagram showing embodiments of resulting structures for each process step of FIG. 4A. Collectively, FIGS. 4A and 4B are designated as FIG. 4.

As shown in FIG. 4, one embodiment of the process comprises the step of depositing 410 a higher-density, lower-etch-rate layer onto a substrate, which results in a structure 415 with a substrate having an etchable layer deposited thereon. The process of FIG. 4 further comprises the step of depositing 420 a lower-density, higher-etch-rate layer onto the higher-density, lower-etch-rate layer, which results in the structure 425 having two etchable layers atop the substrate. Stated differently, the first deposited 410 layer has a lower density than the second deposited 420 layer, and the first deposited 410 layer has a lower etching rate than the second deposited 420 layer. It should be appreciated that the deposited 410, 420 etchable layers comprise silicon-based material, such as, for example, a silicon oxide (SiOx), a silicon nitride (SiNx), a silicon oxynitride (SiOxNy), or any combination thereof.

Continuing with FIG. 4, the deposited 410, 420 layers are etched 430 to form an irregular surface, such as that shown in the structure 435 of FIG. 4. Preferably, the irregular surface comprises microbumps that cause light to scatter. An enlarged view of one embodiment of this structure 435 is shown in FIG. 3. For some embodiments, the etchable layers are etched 430 using a buffered hydrofluoric acid (HF), such as, for example an approximately 1 weight percent (wt %) to approximately 4 wt % HF solution. After etching 430, the process deposits 440 an OLED stack onto the irregular surface.

By employing the process of FIG. 4 and forming microbumps or other irregularities, the resulting OLED structure 445 provides greater light scattering, thus improving light out-coupling as compared to conventional OLED structures.

Any process descriptions or blocks in flow charts should be understood as representing modules, segments, or portions of code which include one or more executable instructions for implementing specific logical functions or steps in the process, and alternate implementations are included within the scope of the preferred embodiment of the present disclosure in which functions may be executed out of order from that shown or discussed, including substantially concurrently or in reverse order, depending on the functionality involved, as would be understood by those reasonably skilled in the art of the present disclosure.

Although exemplary embodiments have been shown and described, it will be clear to those of ordinary skill in the art that a number of changes, modifications, or alterations to the disclosure as described may be made. All such changes, modifications, and alterations should therefore be seen as within the scope of the disclosure.

1. An apparatus, comprising:
a substantially-transparent glass or plastic substrate having a refractive index of approximately 1.5;
a plurality of microbumps formed above the substantially-transparent glass or plastic substrate, the plurality of microbumps being configured to scatter light, each of the plurality of microbumps comprising:
an upper etchable layer having a refractive index of approximately 1.7, the upper etchable layer comprising a first silicon-based inorganic material, the first silicon-based inorganic material being one selected from the group consisting of: a silicon oxide, a silicon nitride, a silicon oxynitride, and a combination thereof; and
a lower etchable layer interposed between the upper etchable layer and the substantially-transparent glass or plastic substrate, the lower etchable layer having a density that is higher than a density of the upper etchable layer, the lower etchable layer further having an etching rate that is lower than an etching rate of the upper etchable layer, the lower etchable layer further having a refractive index of approximately 1.6, the lower etchable layer comprising a second silicon-based inorganic material, the second silicon-based inorganic material being one selected from the group consisting of: a silicon oxide, a silicon nitride, a silicon oxynitride, and a combination thereof;
a first electrode layer formed above the substantially-transparent glass or plastic substrate and the plurality of microbumps, the first electrode layer having a refractive index that is greater than the refractive index of the upper etchable layer, the first electrode layer being an anode layer;
an organic light-emitting diode (OLED) stack formed above the first electrode layer, the OLED stack comprising:
a hole injection layer (HIL);
a hole transport layer (HTL) adjacent to the HIL;
an emission layer (EML) adjacent to the HIL;
an electron transport layer (ETL) adjacent to the EML; and
an electron injection layer (EIL) adjacent to the ETL; and
a second electrode layer formed atop the OLED stack, the second electrode layer and the first electrode layer configured to provide an electrical current through the OLED stack, the second electrode layer being different from the first electrode layer, the second electrode layer being a cathode layer;
wherein each of the plurality of microbumps is smoothly tapered.

2. An apparatus, comprising:
a substrate having a first refractive index;
a plurality of irregularities formed above the substrate, the irregularities being configured to scatter light, each of the plurality of irregularities comprising:
an upper etchable layer having a second refractive index, the second refractive index being higher than the first refractive index; and
a lower etchable layer interposed between the upper etchable layer and the substrate, the lower etchable layer having a third refractive index, and the third refractive index being lower than the second refractive index;
a first electrode layer formed above the substrate and the irregularities, the first electrode layer having a fourth refractive index, the fourth refractive index being higher than the third refractive index;
an organic light-emitting diode (OLED) stack formed above the first electrode layer; and
a second electrode layer formed atop the OLED stack, the second electrode layer and the first electrode layer configured to provide an electrical current through the OLED stack;
wherein:
the upper etchable layer has a first density and a first etching rate;
the lower etchable layer has a second density, the second density being higher than the first density, the lower etchable layer further having a second etching rate, the second etching rate being lower than the first etching rate; and
each of the plurality of irregularities is smoothly tapered.

3. The apparatus of claim 2, wherein:
the upper etchable layer has a first density, the upper etchable layer further having a first etching rate; and
the lower etchable layer has a second density, the second density being higher than the first density, the lower etchable layer further having a second etching rate, the second etching rate being lower than the first etching rate.

4. The apparatus of claim 2, further comprising an interface where the OLED stack is formed above the first electrode layer, the interface having interface irregularities.

5. The apparatus of claim 2, wherein the first electrode layer is a transparent anode layer, and wherein the second electrode layer is a metal cathode layer.

6. The apparatus of claim 5, wherein the transparent anode layer comprises indium tin oxide (ITO), and wherein the metal cathode layer comprises:
aluminum (Al);
silver (Ag); or
any combination thereof.

7. The apparatus of claim 2, wherein the first refractive index is approximately 1.5.

8. The apparatus of claim 2, wherein the third refractive index is approximately 1.6.

9. The apparatus of claim 2, wherein the third refractive index is between approximately 1.4 and approximately 1.5.

10. The apparatus of claim 2, wherein the second refractive index is approximately 1.7.

11. The apparatus of claim 2, wherein the second refractive index is between approximately 1.6 and approximately 1.7.

12. The apparatus of claim 2, wherein the fourth refractive index is approximately 1.8.

13. The apparatus of claim 2, wherein the upper etchable layer comprises a silicon oxide (SiOx), a silicon nitride (SiNx), a silicon oxynitride (SiOxNy), or any combination thereof.

14. The apparatus of claim 2, wherein the lower etchable layer comprises a silicon oxide (SiOx), a silicon nitride (SiNx), a silicon oxynitride (SiOxNy), or any combination thereof.

15. The apparatus of claim 2, wherein the irregularities are microbumps.

16. A process, comprising:
depositing a first etchable layer onto a substrate, the first etchable layer having a first density, the first etchable layer having a first etch rate, the first etchable layer having a first index of refraction;
depositing a second etchable layer onto the first etchable layer, the second etchable layer having a second density, the second etchable layer having a second etch rate, the second etchable layer having a second index of refraction, the second density being lower than the first density, the second etch rate being higher than the first etch rate, the second index of refraction being higher than the first index of refraction;
etching portions of the first etchable layer and portions of the second etchable layer to form an irregular surface; and
depositing layers of an organic light-emitting diode (OLED) stack onto the irregular surface.

17. The process of claim 16, wherein depositing the first etchable layer comprises depositing a first layer of silicon-based material onto the substrate, the first layer of silicon-based material being a silicon oxide (SiOx), a silicon nitride (SiNx), a silicon oxynitride (SiOxNy), or any combination thereof.

18. The process of claim 17, wherein depositing the second etchable layer comprises depositing a second layer of silicon-based material onto the first etchable layer, the second layer of silicon-based material being a silicon oxide (SiOx), a silicon nitride (SiNx), a silicon oxynitride (SiOxNy), or any combination thereof.

19. The process of claim 16, wherein etching portions of the first etchable layer and portions of the second etchable layer comprises using a buffered hydrofluoric acid (HF).

20. The process of claim 19, wherein etching portions of the first etchable layer and portions of the second etchable layer comprises using a buffered hydrofluoric acid (HF) having a HF concentration that is between approximately 1 weight percent (wt %) and approximately 4 wt %.
